(19) United States
(12) Patent Application Publication
(10) Pub. No.: US 2009/0189297 A1
(43) Pub. Date: Jul. 30, 2009

(54) SEMICONDUCTOR DEVICE

(75) Inventors: Katsumi Sugawara, Tokyo (JP); Fumitomo Watanabe, Tokyo (JP)

Correspondence Address: MCDERMOTT WILL & EMERY LLP, 600 13TH STREET, N.W., WASHINGTON, DC, 20005-3096, US

(73) Assignee: ELPIDA MEMORY, INC.

(21) Appl. No.: 12/360,381

(22) Filed: Jan. 27, 2009

(30) Foreign Application Priority Data
Jan. 29, 2008 (JP) 2008-017386

(51) Int. Cl. H01L 23/48

(52) U.S. Cl. 257/778; 257/E23.01

(57) ABSTRACT

To provide a semiconductor device having high reliability by reducing the bending of a semiconductor device and mitigating stress exerted on external terminals. In a semiconductor device 1 having a semiconductor chip 9 mounted on a wiring substrate 2 comprising a base member 3 having a predetermined conductive pattern formed on both surfaces, slits 8 that penetrate the base member 3 in the vertical direction of the base member 3 are provided. When the semiconductor chip 9 and a wire 12 are sealed with resin, the same resin is used to fill the slits 8.

### REFERENCE TO RELATED APPLICATION

This application is based upon and claims the benefit of the priority of Japanese patent application No. 2008-017386 filed on Jan. 29, 2008, the disclosure of which is incorporated herein in its entirety by reference thereto.

### FIELD OF THE INVENTION

The present invention relates to a semiconductor device comprising a semiconductor chip on its wiring substrate.

### BACKGROUND OF THE INVENTION

A typical BGA-type (Ball Grid Array-type) semiconductor device comprises a wiring substrate and a semiconductor chip on one side of the wiring substrate. Out of two main sides of the wiring substrate, a plurality of connection pads are formed on the side which the semiconductor chip is on, and a plurality of lands electrically connected to the connection pads are formed on the other side. The connection pads and an electrode pad of the semiconductor chip are electrically connected by wires. Solder balls that function as external terminals are provided on the lands. Further, at least the semiconductor chip and the wires are covered with a sealing body (sealing resin) made up of insulating resin.

For instance, during the manufacturing process of the BGA-type semiconductor device described above, the semiconductor device might be bent because of a difference between the sealing resin and the wiring substrate in the coefficient of thermal expansion, and as a result, properly mounting the solder balls, which will become the external terminals, on the wiring substrate becomes difficult. Further, if the semiconductor device is bent, mounting the semiconductor device on a secondary mounting substrate such as a motherboard will be difficult.

Furthermore, even after the semiconductor device has been mounted on the secondary mounting substrate such as a motherboard, stress is exerted on external terminals provided around the semiconductor device and external terminals provided near the edge ends of the semiconductor chip due to thermal stress, and as a result, these external terminals might get damaged and the reliability of the semiconductor device might deteriorate.

For instance, a technology for preventing such damage to the external terminals disposed around the semiconductor device is disclosed in Patent Document 1. The summary of the technology disclosed in Patent Document 1 is that external terminals disposed in the outermost corners of the semiconductor device have sizes larger than those of other external terminals.

Further, technologies for mitigating the stress on the external terminals, in which a groove is provided between the external terminals, are disclosed in Patent Documents 2 and 3.

### [Patent Document 1]

Japanese Patent Kokai Publication No. JP-P2006-294656A

### [Patent Document 2]

Japanese Patent Kokai Publication No. JP-A-11-260960

### [Patent Document 3]

Japanese Patent Kokai Publication No. JP-P2000-12732A

### SUMMARY OF THE DISCLOSURE

The entire disclosures in the above-mentioned Patent Documents are incorporated herein by reference thereto. The following analysis is given by the present invention.

If the external terminals in the outermost corners are enlarged as in the technology disclosed in Patent Document 1, it will be less likely that the external terminals will be damaged. However, the technology disclosed in Patent Document 1 does not mitigate the stress on the external terminals and therefore does not offer a fundamental solution for the mitigation of the stress exerted on the external terminal.

If a groove is provided between the external terminals as disclosed in Patent Document 2 or 3, the stress on the external terminals can be mitigated to a certain degree, however, the wiring substrate will be bent and as a result, the semiconductor device will be bent as well. In such a case where the semiconductor device is bent, the external terminals of the secondary-mounted semiconductor device might get damaged. Furthermore, the mountability of the semiconductor device will deteriorate because of the bend. Thus, there is much to be desired in the art.

After investigating the problems in Patent Documents 2 and 3, we predict that the problems are caused by the following factors. Since the grooves provided between the external terminals in Patent Documents 2 and 3 do not penetrate a base member of the wiring substrate, the wiring substrate is not divided and expands further at the time of thermal expansion. Further, as a result of forming the grooves on the wiring substrate, some parts of the wiring substrate become thicker than others. This makes the wiring substrate more susceptible to the bending caused by the difference in the coefficient of thermal expansion. Further, due to the fact that the wiring substrate has the parts (where the grooves are formed) thinner than others, the semiconductor device is more likely to bend because of the difference between the wiring substrate and the sealing resin in the coefficient of thermal expansion. Such bending may hurt the mountability of the semiconductor device. The present invention seeks to solve one or more of the above problems, or to improve upon those problems at least in part.

According to a first aspect of the present invention, as a first semiconductor device, there is provided a semiconductor device comprising a semiconductor chip mounted on a wiring substrate including a base member having a predetermined conductive pattern formed on both surfaces thereof wherein the conductive pattern and the semiconductor chip are electrically connected, and slits that penetrate the base member in a vertical direction of the base member are provided.

Further, according to a second aspect of the present invention, there is provided a second semiconductor device wherein the slits are formed across the base member in a direction perpendicular to the vertical direction in the first semiconductor device.

Further, according to a third aspect of the present invention, there is provided a third semiconductor device, wherein in the first or second semiconductor device, the predetermined conductive pattern includes a plurality of conductive areas disposed interposing the slits therebetween, further comprising a connecting wiring that electrically connects the conductive areas so as to bridge the slits.

Further, according to a fourth aspect of the present invention, there is provided a fourth semiconductor device wherein in any one of the first to third semiconductor devices, the slits are disposed near the edge ends of the semiconductor chip.

Further, according to a fifth aspect of the present invention, there is provided a fifth semiconductor device, wherein in any one of the first to fourth semiconductor devices, further comprising a plurality of external terminals provided on the wiring substrate wherein the slits are formed between a first external terminal, which is one of the external terminals located outermost in a predetermined direction, and a second external terminal, which is one of the external terminals located inside of the first external terminal in the predetermined direction and adjacent to the first external terminal, so as to extend in a direction perpendicular to the predetermined direction.

Further, according to a sixth aspect of the present invention, there is provided a sixth semiconductor device, wherein in any one of the first to fifth semiconductor devices, the slits penetrate the wiring substrate in the vertical direction of the wiring substrate.

Further, according to a seventh aspect of the present invention, there is provided a seventh semiconductor device, wherein in any one of the first to sixth semiconductor devices, the slits are filled with a resin.

Further, according to a eighth aspect of the present invention, there is provided an eighth semiconductor device, wherein in the seventh semiconductor device, semiconductor chip is sealed with predetermined resin and the resin that fills the slits is the predetermined resin.

Further, according to a ninth aspect of the present invention, there is provided a ninth semiconductor device, wherein in the eight semiconductor device, the slits are provided in a direction in which the predetermined resin is injected when the semiconductor chip is sealed with the predetermined resin.

Further, according to a tenth aspect of the present invention, there is provided a tenth semiconductor device, wherein in any one of the first to ninth semiconductor devices, the semiconductor chip is flip-chip mounted on the wiring substrate.

Meritorious effects of various aspect of the present invention are mentioned below, however, not limited thereto.

In the first semiconductor device according to the present invention, the slits that penetrate the base member of the wiring substrate in the vertical direction are provided. As a result, for instance, even when the semiconductor chip is sealed with resin, the bending of the semiconductor device caused by the difference between the wiring substrate and the sealing body in the coefficient of thermal expansion can be reduced and the stress applied to the external terminals can be mitigated.

In the second semiconductor device according to the present invention, the slits are formed across the base member of the wiring substrate. As a result, the manufacturing method becomes simpler and the cost is reduced, in addition to the effect that the stress is mitigated evenly.

In the third semiconductor device according to the present invention, the electrical connection wiring (means) that bridges the parts of the wiring substrate divided by the slits is provided. Therefore, a FAN-IN semiconductor device can be realized even when the wiring substrate is divided by the slits.

In the fourth or fifth semiconductor device according to the present invention, since the slits are formed in the areas where the thermal stress is likely to occur, the stress applied to the external terminals can be more effectively reduced.

In the sixth semiconductor device according to the present invention, the slits penetrate not only the base member, but also the conductive pattern formed on the base member. A merit of having this structure is that, for instance, such slits can easily be formed by dicing means in a process after the conductive pattern has been formed on the base member.

In the seventh semiconductor device according to the present invention, the slits are filled with a resin. More particularly, in the eighth semiconductor device according to the present invention, the resin filling the slits is a sealing resin. Therefore the adhesiveness of the wiring substrate and the sealing resin is improved.

In the ninth semiconductor device according to the present invention, the slits are formed along the direction in which the sealing resin is injected. As a result, when the semiconductor chip is sealed with the resin, the slits can be smoothly filled with the resin.

In the tenth semiconductor device according to the present invention, the semiconductor chip is flip-chip mounted on the wiring substrate. As a result, the semiconductor device can be made thinner.

### BRIEF DESCRIPTION OF THE DRAWINGS

The above features and advantages of the present invention will be more apparent from the following description of certain preferred examples taken in conjunction with the accompanying drawings, in which:

FIG. 1 is a cross-sectional view of a semiconductor device according to a first example of the present invention.

FIG. 2 is a plan view showing a bottom surface (where external terminals are formed) of the semiconductor device shown in FIG. 1.

FIG. 3 is a plan view of a wiring motherboard used in the manufacturing of the semiconductor device shown in FIG. 1.

FIGS. 4A to 4E are cross-sectional views showing a manufacturing flow for manufacturing the semiconductor device shown in FIG. 1.

FIG. 5 is a plan view of the state of FIG. 4C, i.e., the wiring substrate after the sealing body has been formed over it.

FIG. 6 is a cross-sectional view of a semiconductor device according to a second example of the present invention.

FIG. 7 is a plan view of a wiring motherboard used in the manufacturing of the semiconductor device shown in FIG. 6.

FIGS. 8A to 8F are cross-sectional views showing a manufacturing flow for manufacturing the semiconductor device shown in FIG. 6.

FIGS. 9A to 9F are cross-sectional views showing a manufacturing flow for manufacturing a semiconductor device according to a third example of the present invention.

FIG. 10 is a cross-sectional view of a semiconductor device according to a fourth example of the present invention.

FIG. 11 is a cross-sectional view of a semiconductor device according to a fifth example of the present invention.

FIG. 12 is a cross-sectional view of a semiconductor device according to a sixth example of the present invention.

FIGS. 13A to 13F are cross-sectional views showing a manufacturing flow for manufacturing the semiconductor device shown in FIG. 12.

### EXPLANATION OF SYMBOLS

1: semiconductor device
2: wiring substrate (package board)
3: base member
4: solder resist
5: connection pad
6: land
7: solder ball
8: slit
9: semiconductor chip
10: adhesive
11: electrode pad
12: wire
13: sealing body (sealing resin)
14: wiring motherboard
15: product forming portion(s)
16: frame portion
17: aligning hole
18: cull
19: runner
20: dicing tape
21: mark
22: bump (for flip-chip mounting)
23: wire
24: DAF

### DETAILED DESCRIPTION OF THE PREFERRED MODES

A semiconductor device according to examples of the present invention will be described in detail with reference to the drawings.

### First Example

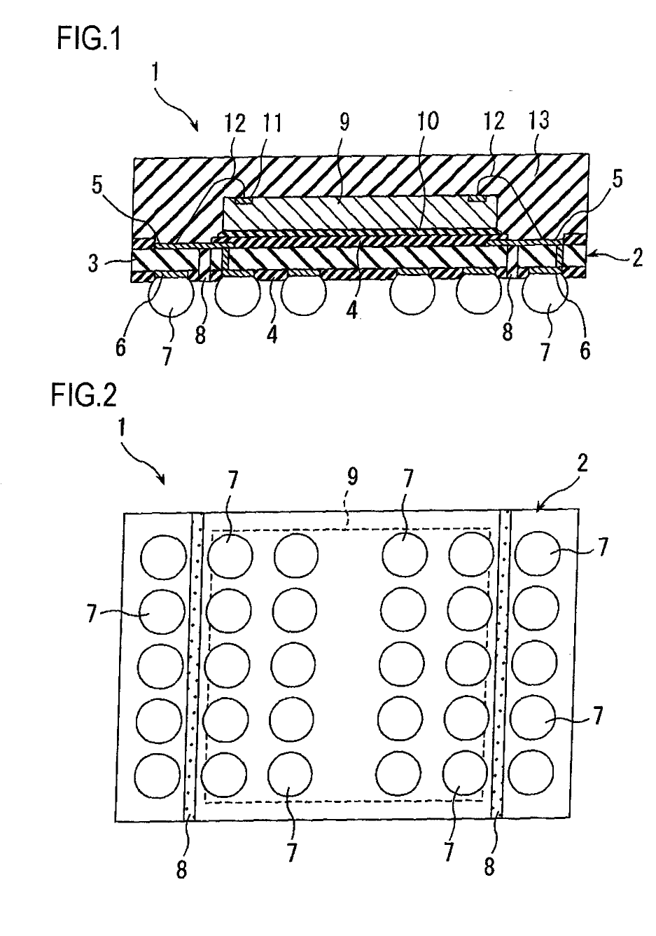

FIG. 1 is a cross-sectional view of a semiconductor device according to a first example of the present invention. FIG. 2 is a plan view showing a bottom surface (where external terminals are formed) of the semiconductor device according to the same example.

The semiconductor device 1 according to the present example comprises a wiring substrate (or a package board) 2 having an approximately rectangular shape when it is viewed from above. The wiring substrate 2 is, for instance, a glass-epoxy substrate of thickness 0.25 mm, and a wiring of a predetermined conductive pattern is formed on both surfaces of a base member 3. The wiring is partially covered with an insulating film or for instance a solder resist 4. A plurality of connection pads 5 are formed on an area of the wiring formed on a side of the wiring substrate 2 and not covered with the solder resist 4. On the other hand, a plurality of lands 6 are formed an area of the wiring formed on the other side of the wiring substrate 2 and not covered with the solder resist 4. Further, the connection pads 5 and the corresponding lands 6 are electrically connected respectively by the wiring (including vias) formed on the wiring substrate 2.

A conductive ball, more concretely a solder ball 7, which will become the external terminal, is formed on each of the plurality of lands 6. The solder balls 7 in the present example are disposed at a predetermined interval and in a grid array as shown in FIG. 2.

In the present example, slits 8 that penetrate the base member 3 are formed between the outermost column(s) of the solder balls 7 and the inner adjacent column(s) of the solder balls (between the column(s) of the solder balls 7 provided nearest to and along with the shorter sides of the wiring substrate and the adjacent column(s) of the solder balls 7 in FIG. 2) on the wiring substrate 2. Further, in the present example, the positions where the slits 8 are formed are also near the edge ends of a semiconductor chip 9, as described below.

Moreover, the slits 8 in the present example are formed so as to go across the base member 3, as shown in FIG. 2. More concretely, the slits 8 extend from one of two opposing sides (opposing longer sides of the wiring substrate 2 in FIG. 2) of the wiring substrate 2 having an approximately square shape to the other side. The slits 8 penetrate the base member 3 vertically and thus contribute to the mitigation of the problematic stress. Furthermore, when the slits are provided across the base member 3 as in the present example, a better balance is obtained since the stress does not concentrate on one point and the manufacturing process becomes easier, as described later.

As shown in FIG. 1, on the surface of the wiring substrate 2 where the connection pads 5 are formed, the wiring is formed so as to bridge the slits 8 and the parts of the wiring substrate divided by the slits are electrically connected. In other words, a conductor pattern formed on the base member 3 of the wiring substrate 2 includes areas disposed interposing the slits 8 therebetween and these areas are electrically connected by the wiring pattern formed so as to bridge the slits 8.

Further, in an approximately central area on the surface of the wiring substrate 2 where the connection pads 5 are formed, the semiconductor chip 9 is mounted through an insulating adhesive 10. Across a surface of the semiconductor chip 9, for instance, a logic circuit or memory circuit is formed. Furthermore, a plurality of electrode pads 11 are formed in areas near and surrounding the semiconductor chip 9, and a passivation film, not shown in the drawing, is formed on a surface of the semiconductor chip 9, excluding the electrode pads, to protect the surface where the circuit is formed.

As shown in FIG. 1, the electrode pads 11 of the semiconductor chip 9 are electrically connected to the corresponding connection pads 5 of the wiring substrate 2 by wiring them using a conductive wire 12. The wire 12 is made up of, for instance, gold or copper.

On the surface of the wiring substrate 2 on which the semiconductor chip 9 is mounted, the semiconductor chip 9 and the wire 12 are covered with a sealing body 13. The sealing body 13 is made up of, for instance, a thermosetting resin such as epoxy resin. In the present example, by configuring so that the sealing body 13 gets into the slits 8 of the wiring substrate 2, the adhesive area of the sealing body 13 and the wiring substrate 2 becomes larger, improving the adhesiveness of the wiring substrate 2 and the sealing body (sealing resin) 13.

As described, in the semiconductor device having the semiconductor chip 9 on the wiring substrate 2, by providing the slits 8 that vertically penetrate the base member 3 between the plurality of external terminals (the solder balls 7) on the base member 3 of the wiring substrate 2, the bending of the semiconductor device 1 caused by the difference between the wiring substrate 2 and the sealing body 13 in the coefficient of thermal expansion can be reduced and the thermal stress applied to the wiring substrate 2 can be mitigated.

Further, since the base member 3 of the wiring substrate 2 is divided by the slits 8, the slits 8 act as a buffer and reduce the stress applied on the solder balls 7 (the external terminals). On the base member 3 of the wiring substrate 2, the problematic stress tends to occur between the solder balls 7 (the external terminals) disposed near the edge ends of the semiconductor chip 9 or between the solder balls 7 (the external terminals) disposed near the outermost of the wiring substrate 2 and the solder balls 7 (the external terminals) adjacent to the outermost solder balls. The stress exerted on the solder balls 7 (the external terminals) can be more effectively reduced by providing the slits 8 in these areas. In addition, since the wiring is formed so as to bridge the slits 8, it is possible to electrically connect the parts of the wiring substrate 2 divided by the slits 8. As a result, the reliability of the semiconductor device can be improved.

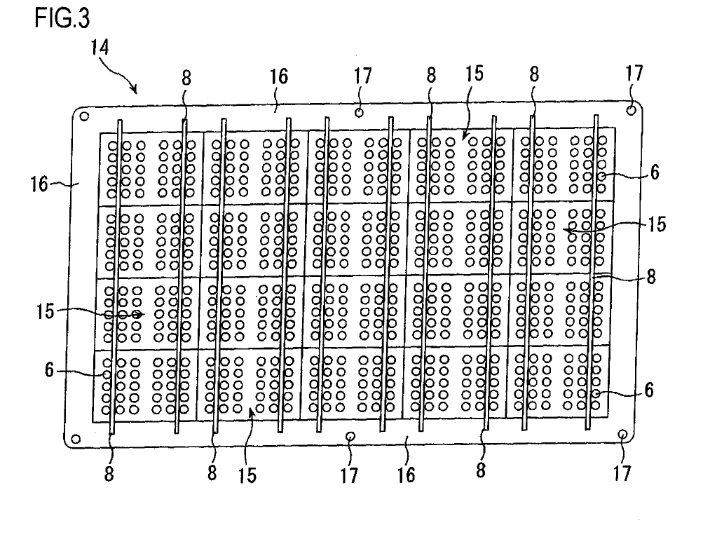

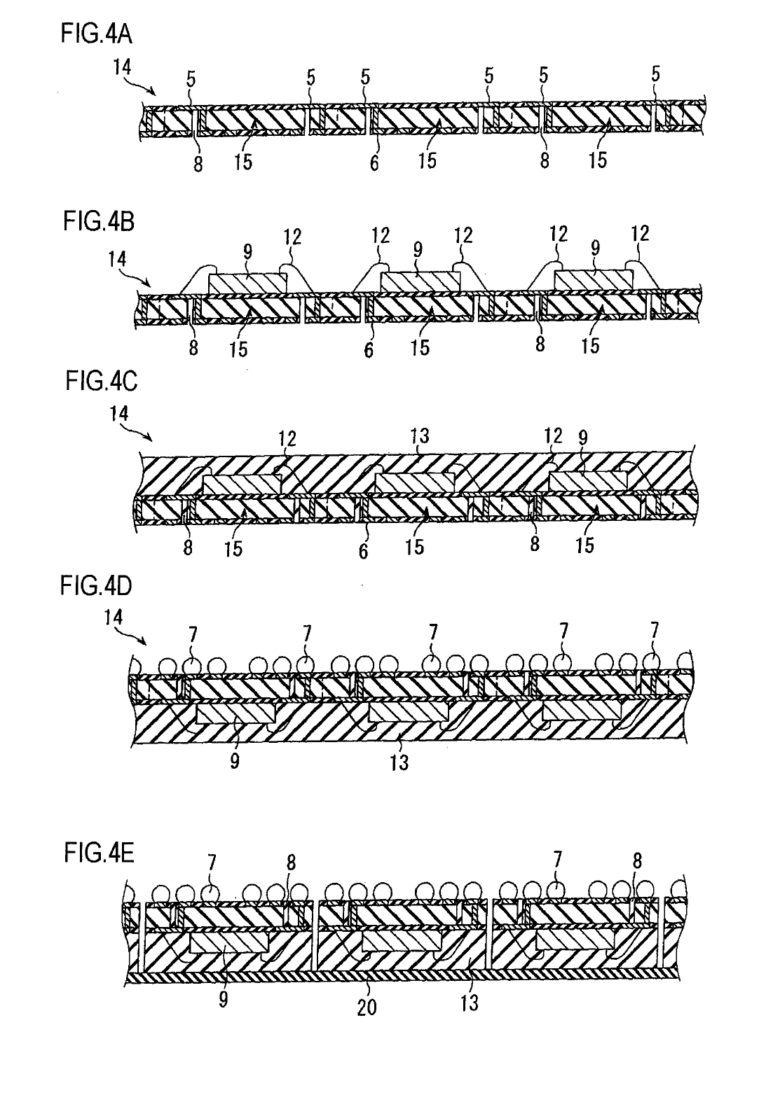

A method for manufacturing the semiconductor device 1 according to the first example will be described with reference to FIGS. 3 to 5. FIG. 3 is a plan view of a wiring motherboard used in the manufacturing of the semiconductor device according to the present example. FIGS. 4A to 4E are cross-sectional views showing a manufacturing flow for manufacturing the semiconductor device according to the present example. FIG. 5 is a plan view of the wiring substrate after the sealing body has been formed over it.

First, the wiring motherboard 14 as shown in FIG. 3 and FIG. 4A is prepared. The wiring motherboard 14 used in the present example is processed following a MAP (Mold Array Process) and is constituted by a plurality of product forming portions 15 and a frame portion 16 provided around the product forming portions as shown in FIG. 3. More concretely, the wiring motherboard 14 in the present example has a base member made of glass-epoxy. The product forming portions 15 shown in the drawing are disposed in a matrix pattern. The product forming portions 15 have the same configuration as that of the wiring substrate 2 described above and after they have been cut off, each piece becomes a wiring substrate 2, therefore the explanation of the product forming portions will be omitted. Aligning holes 17 are provided at a predetermined interval on the frame portion 16, making conveyance and position determining possible. Further, dicing lines are marked between the product forming portions 15. The aforementioned slits 8 on the wiring substrate 2 are provided consecutively over the plurality of product forming portions 15, parallel to the shorter sides of the wiring motherboard 14, as shown in FIG. 3. Each piece of the product forming portions 15 is divided by the slits 8, however, they are still one piece at this point since they are supported by the frame portion 16. Each of the product forming portions 15 is electrically connected within each product forming portion since the wiring bridging the slits 8 is formed in them as described above. The wiring motherboard 14 as described above can be obtained by forming the slits 8 on a base member made of glass-epoxy and then forming wiring patterns on both surfaces of the base member.

Next, as shown in FIG. 4B, the bottom surface of the semiconductor chip 9 is adhered and fixed over a surface of each product forming portion 15 of the wiring motherboard 14 through an insulating adhesive 10 using a die bonding apparatus not shown in the drawing. Then the electrode pads 11 over a surface of the semiconductor chip 9 and the connection pads 5 of the product forming portion 15 are wired with a conductive wire 12 using a wire bonding apparatus not shown in the drawing. The wire 12 is made of, for instance, gold. It is melted by the wire bonding apparatus not shown in the drawing, and the wire with a ball formed on its tip is bonded onto the electrode pad 11 of the semiconductor chip 9 by means of ultrasonic thermocompression bonding. Then the wires are formed into a predetermined loop shape and the back end of each wire is bonded to a corresponding connection pad 5 by means of ultrasonic thermocompression bonding, for instance.

Next, as shown in FIG. 4C, the sealing body 13 made of insulating resin and integrally covering each of the product forming portions 15 of the wiring motherboard 14 is formed. For instance, the sealing body 13 can be formed by clamping the wiring motherboard 14 with a molding die comprised of the upper and lower molding dies of a transfer molding apparatus not shown in the drawing, injecting thermosetting epoxy resin into a cavity formed by the upper and lower molding dies from a gate, thermally curing it after the cavity has been filled.

FIG. 5 shows the wiring motherboard 14 still having culls 18 and runners 19. In FIG. 5, the gate is positioned along the longer side of the wiring motherboard 14, to which the plurality of runners 19 are connected. On the wiring motherboard 14, the slits 8 are formed along the direction in which the sealing resin is injected from the gate. The resin is smoothly filled into the slits 8 as well.

Next, as shown in FIG. 4D, using a ball mounter not shown in the drawing, the solder balls 7 are mounted on top of the plurality of lands 6 disposed in a grid array on the other surface of the wiring motherboard 14 and bump electrodes, which will become the external terminals, are formed. In the ball mounting process, using a mounting tool (not shown in the drawing) on which a plurality of suction holes are formed corresponding to the positions of the lands on the wiring motherboard 14, the solder balls 7 are placed on the suction holes of the mounting tool; flux is transferred to and formed on the balls placed; and the balls are mounted on the lands 6 of the wiring motherboard 14 en bloc. After the balls have been mounted, the bump electrodes (the external terminals: the solder balls 7) are formed by applying reflow soldering.

Next, as shown in FIG. 4E, the wiring motherboard 14 is diced along with the dicing lines using a dicing apparatus not shown in the drawing, being divided into pieces of the product forming portions 15. For instance, the substrate dicing may be performed as follows. First, the sealing body 13 of the wiring motherboard 14 is glued to a dicing tape 20, which is used to support the wiring motherboard 14. Next, using a dicing blade not shown in the drawing, the wiring motherboard 14 is diced along with the dicing lines extending in longitudinal and lateral directions, and the wiring motherboard 14 is divided into pieces. After the dicing is completed, the semiconductor device 1 shown in FIG. 1 can be obtained by picking it up from the dicing tape 20.

According to the example described above, the bending of the semiconductor device 1 caused by the difference between the wiring substrate 2 and the sealing body 13 in the coefficient of thermal expansion can be reduced and the stress applied to the solder balls 7 (the external terminals) can be mitigated by providing the slits 8 that vertically penetrate the base member 3 at positions between the plurality of solder balls 7 (the external terminals) on the base member 3 of the wiring substrate 2. Further, the adhesiveness of the wiring substrate 2 and the sealing body 13 can be improved by filling the slits 8 with a resin constituting the sealing body 13. In addition, on the base member 3 of the wiring substrate 2, the thermal stress tends to occur between the solder balls 7 (the external terminals) disposed near the edge ends of the semiconductor chip 9 or between the solder balls 7 (the external terminals) disposed near the outermost of the wiring substrate 2 and the solder balls 7 (the external terminals) adjacent to the outermost solder balls. By providing the slits 8 in these areas, the stress exerted on the solder balls 7 (the external terminals) can be more effectively reduced. Furthermore, since the connection means (i.e., wiring or conductive pattern) is formed so as to electrically connect and bridge between the parts of the wiring substrate divided by the slits 8, a semiconductor device of FAN-IN structure can be realized even with the wiring substrate divided into parts by the slits 8. As described, the reliability of the semiconductor device can be improved.

### Second Example

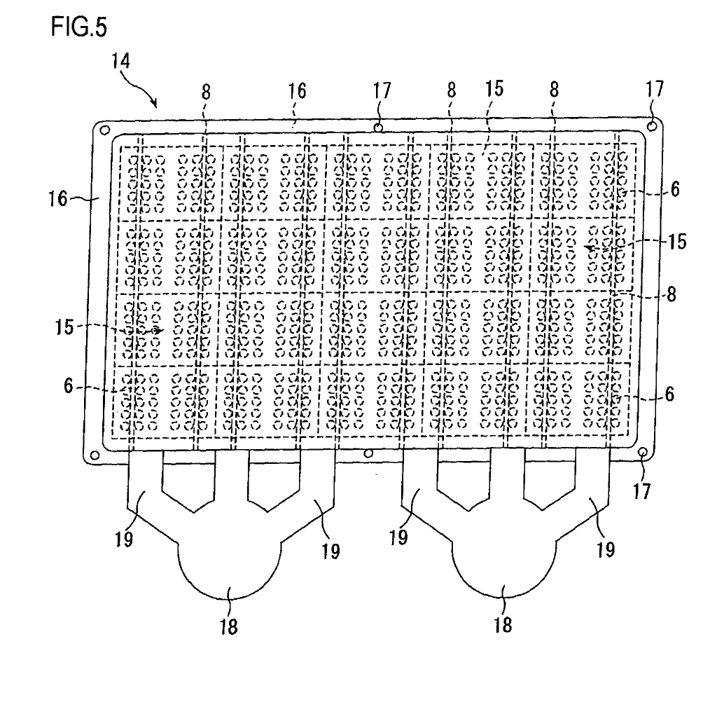

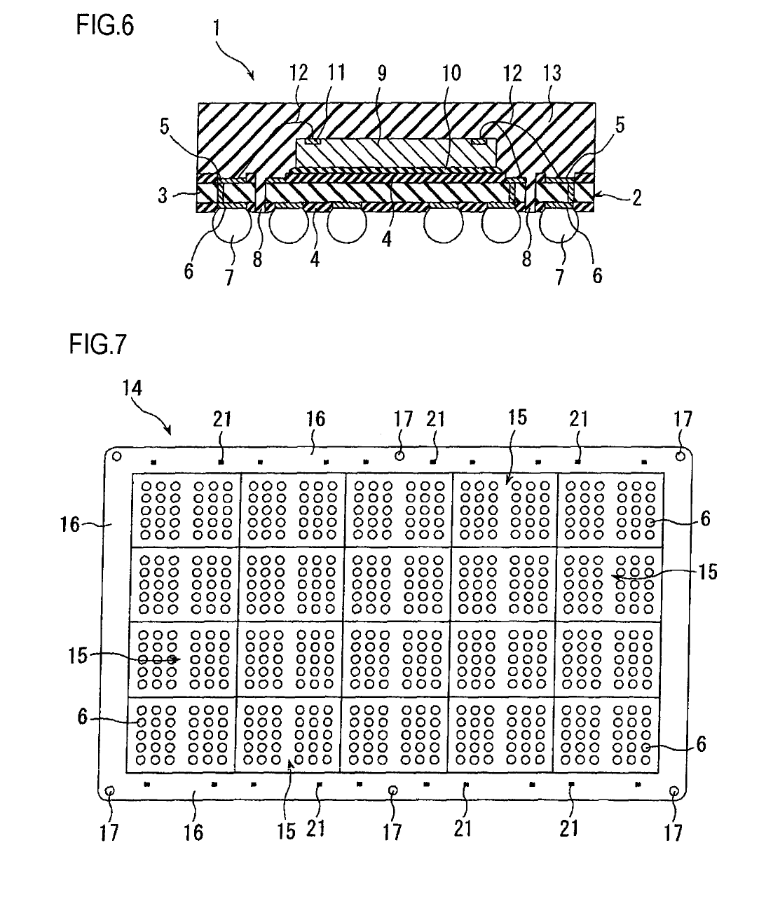

FIG. 6 is a cross-sectional view of a semiconductor device according to a second example of the present invention. The semiconductor device 1 of the present example is a variation of the first example described above. Therefore, in FIG. 6, the constituents same as those in the first example has the same reference symbols used in FIG. 1, and a detailed explanation of them will be omitted.

In the first example described above, the wiring pattern formed across the slits 8 (bridge wiring) is provided, however, such a bridge wiring is not formed in the present example. Instead, since the wiring substrate 2 is divided completely in the present example, the semiconductor chip 9 and the wiring substrate 2 divided by the slits 8 are wired with the wires 12 as shown in FIG. 6.

In the semiconductor device 1 having the configuration as described above according to the present example, the bending of the semiconductor device 1 caused by the difference between the wiring substrate 2 and the sealing body 13 in the coefficient of thermal expansion can be reduced and the thermal stress applied to the wiring substrate 2 can be mitigated as in the first example. Further, in the semiconductor device according to the present example, since no bridge wiring is provided, there is no need to worry that the bridge wiring gets disconnected during a resin sealing process.

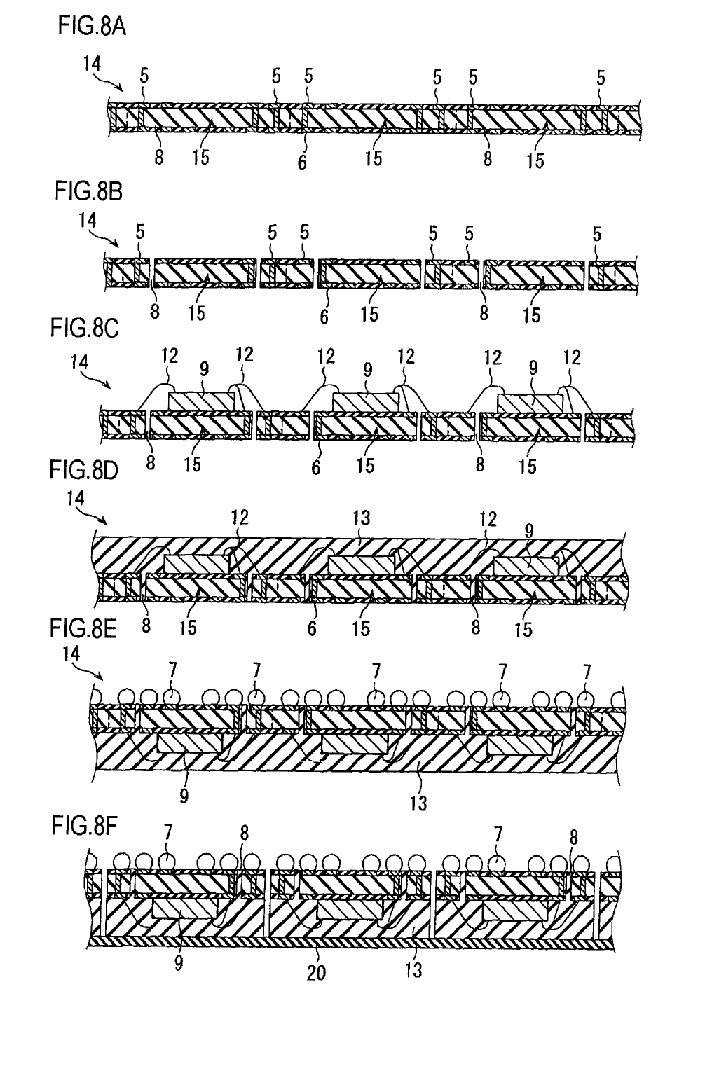

A method for manufacturing the semiconductor device 1 according to the second example will be described with reference to FIGS. 7 to 8.

First, the wiring motherboard 14 as shown in FIG. 7 and FIG. 8A is prepared. As shown in FIG. 7, the wiring motherboard 14 used in the manufacturing of the semiconductor device 1 according to the present example has generally the same configuration as that of the wiring motherboard used in the first example. The present example differs from the first example in that the slits 8 are not formed on the wiring motherboard 14 and marks 21 indicating the positions where the slits 8 are formed on the frame portion 16.

Next, using a dicing apparatus not shown in the drawing, the wiring motherboard 14 is partially diced along with the marks 21 provided on the frame portion 16, and the slits 8 as shown in FIG. 8B are formed. Then, as shown in FIG. 8C, the semiconductor chip 9 is mounted on each of the product forming portions 15 of the wiring motherboard 14, using a die bonding apparatus not shown in the drawing, and the electrode pads 11 of the semiconductor chip 9 and the connection pads 5 of the product forming portion 15 are wired with conductive wires 12 using a wire bonding apparatus not shown in the drawing. Since the bridge wiring is not formed in the semiconductor device 1 according to the present example, the divided parts of the wiring substrate are wired at this time so that they are electrically connected. As one can see by comparing FIGS. 8 and 4, the semiconductor device shown in FIG. 6 can be manufactured by performing the same processes as those of the manufacturing method according to the first example.

### Third Example

A semiconductor device according to a third example of the present invention is a variation of the second example described above and is generally configured identically, however, the third example differs from the second in that the slits 8 are not filled with the sealing resin.

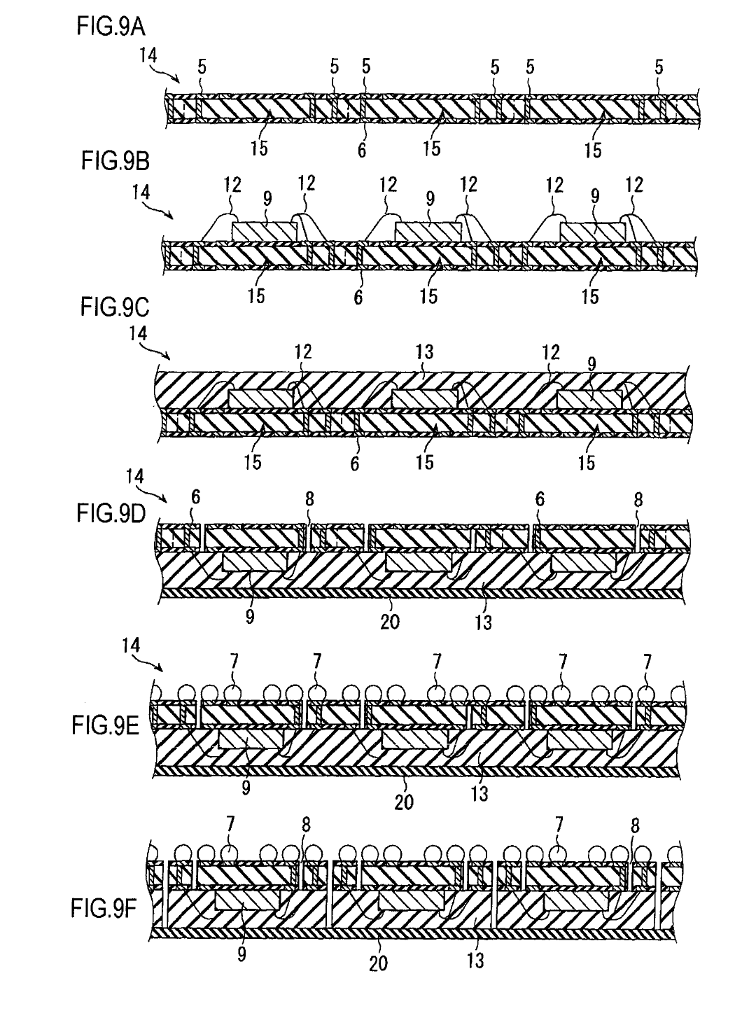

A method for manufacturing the semiconductor device according to the third example will be described with reference to FIGS. 7 and 9. It should be noted that, in FIG. 9, the constituents same as those in the second example has the same reference symbols used in FIG. 8, and a detailed explanation of them will be omitted.

First, the wiring motherboard 14 shown in FIG. 7 and FIG. 9A is prepared in the present example as well.

Next, as shown in FIG. 9B, the semiconductor chip 9 is mounted on each of the product forming portions 15 of the wiring motherboard 14, using a die bonding apparatus not shown in the drawing, and the electrode pads 11 of the semiconductor chip 9 and the connection pads 5 of the product forming portion 15 are wired with the conductive wire 12 using a wire bonding apparatus not shown in the drawing. Since the bridge wiring is not formed in the semiconductor device 1 according to the present example, parts of the wiring substrate, which will be divided because of the formation of the slits 8, are wired at this time so that they are electrically connected.

Next, as shown in FIG. 9C, the sealing body 13 made of insulating resin and integrally covering the product forming portions 15 of the wiring motherboard 14 is formed.

Next, as shown in FIG. 9D, the sealing body 13 is adhered to the dicing tape 20, and the slits 8 are formed using a dicing blade not shown in the drawing while the wiring motherboard 14 is supported by the dicing tape 20. Then, as shown in FIG. 9E, the solder balls 7 are formed. The semiconductor device according to the present example can be obtained by, using a dicing blade not shown in the drawing, dicing the wiring motherboard 14 along with the dicing lines as shown in FIG. 9F and dividing it into pieces.

In the semiconductor device manufactured as described above, the slits 8 are simply openings and the resin constituting the sealing body 13 is not filled into the slits 8. Therefore there is no concern that the slits 8 will have any void. Further, since the slits 8 are yet to be formed at the time of the die bonding and wire bonding, the semiconductor device 9 can be mounted stably.

Note that, in the present example, the sealing body 13 is adhered to the dicing tape 20 when the slits 8 are formed, however, if the wiring motherboard 14 can be held and supported properly using other means during the formation of the slits 8, the dicing tape 20 is not necessary. In this case, the dicing tape is only used in the process shown in FIG. 9F.

### Fourth Example

FIG. 10 is a cross-sectional view of a semiconductor device according to a fourth example of the present invention. The semiconductor device 1 of the present example is a variation of the first example described above. Therefore, in FIG. 10, the constituents same as those in the first example has the same reference symbols used in FIG. 1, and a detailed explanation of them will be omitted.

In the first example, only two slits 8 are formed: between the column of the outermost solder balls 7 and the adjacent column just inside of the outermost column. In the present example, however, at least one slit 8 is formed between each column of the solder balls 7 (the external terminals) as shown in FIG. 10. By increasing the number of the slits 8, the bending of the semiconductor device can be reduced and the thermal stress applied to the wiring substrate 2 can be mitigated.

### Fifth Example

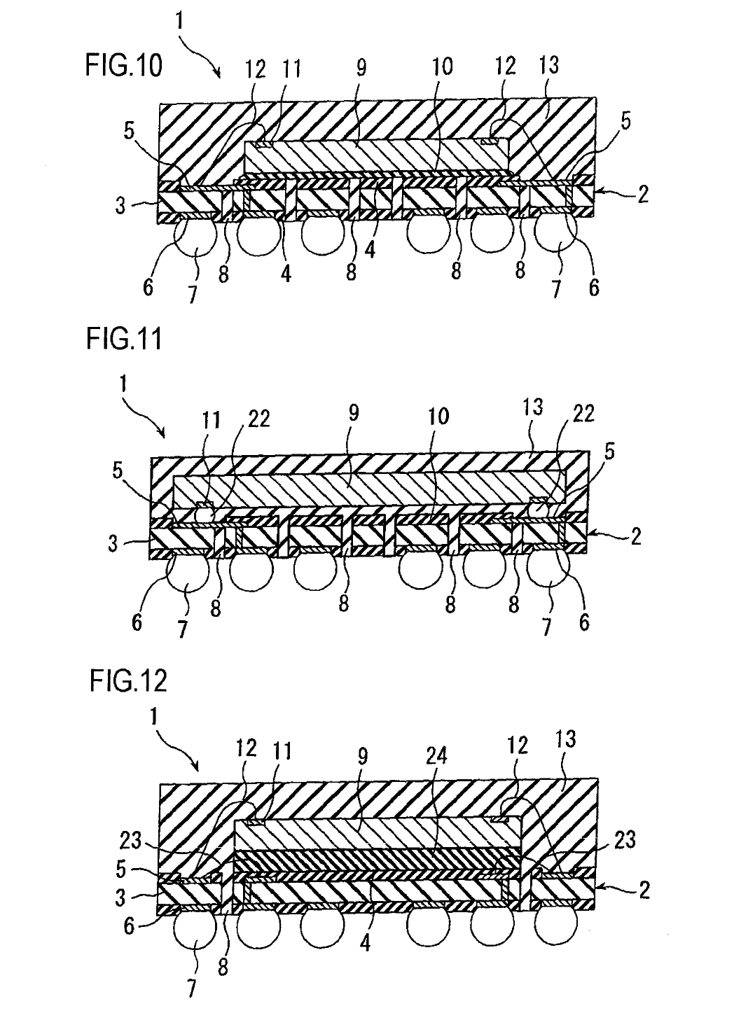

FIG. 11 is a cross-sectional view of a semiconductor device according to a fifth example of the present invention. The semiconductor device 1 according to the present example is a variation of the fourth example described above. Therefore, in FIG. 11, the constituents same as those in the fourth example has the same reference symbols used in FIG. 10, and a detailed explanation of them will be omitted.

In the first to fourth examples described above, the electrode pads 11 of the semiconductor chip 9 and the connection pads 5 of the wiring substrate 2 are connected by the wires 12, however, in the semiconductor device according to the present example, the semiconductor chip 9 is attached with bumps 22, therefore the semiconductor chip 9 is flip-chip connected to the wiring substrate 2 as shown in FIG. 11. In other words, the electrode pads 11 of the semiconductor chip 9 are electrically connected to the connection pads 5 of the wiring substrate 2 via the bumps 22.

In addition to the effects obtained in the first example, the semiconductor device, configured as described, according to the present example, can be highly effective in terms of reducing the bending of the semiconductor device and of mitigating the thermal stress applied to the wiring substrate 2 since the number of the slits 8 is increased as in the fourth example. Furthermore, by flip-chip mounting the semiconductor chip 9, the semiconductor device 1 can be made thinner. In addition, since the slits 8 are formed on the wiring substrate 2, the wiring substrate 2 and the semiconductor chip 9 can be sealed with resin satisfactorily.

### Sixth Example

FIG. 12 is a cross-sectional view of a semiconductor device according to a sixth example of the present invention. The semiconductor device 1 according to the present example is a variation of the second example described above. Therefore, in FIG. 12, the constituents same as those in the second example has the same reference symbols used in FIG. 6, and a detailed explanation of them will be omitted.

The semiconductor chip 9 is adhered to the wiring substrate 2 using the adhesive 10 in all of the examples described above, however, in the present example, as shown in FIG. 12, the divided parts of the wiring substrate 2 are electrically connected by conductive wires 23 and the semiconductor chip 9 is mounted over the wires 23 with a DAF (Die-Attach Film) 24 interposed. The DAF 24 has, for instance, an insulating base member with adhesives provided on both sides and is configured so that the adhesive on the side of the DAF 24 facing the wiring substrate 2 gets between the wires 23, adhering the DAF 24 to the wiring substrate 2. Since the insulating base member of the DAF 24 is interposed between the bottom surface of the semiconductor chip 9 and the wires 23, the wires 23 do not short-circuit.

Even in the case where the slits 8 penetrating the base member 3 or the wiring substrate 2 are provided at the edge ends of the semiconductor chip 9, a FAN-IN semiconductor device can be realized by connecting the divided parts of the wiring substrate 2 with the wires 23.

In the present example, the divided parts of the wiring substrate 2 are electrically connected by the wire 23, however, a film substrate may be used to make the electrical connection.

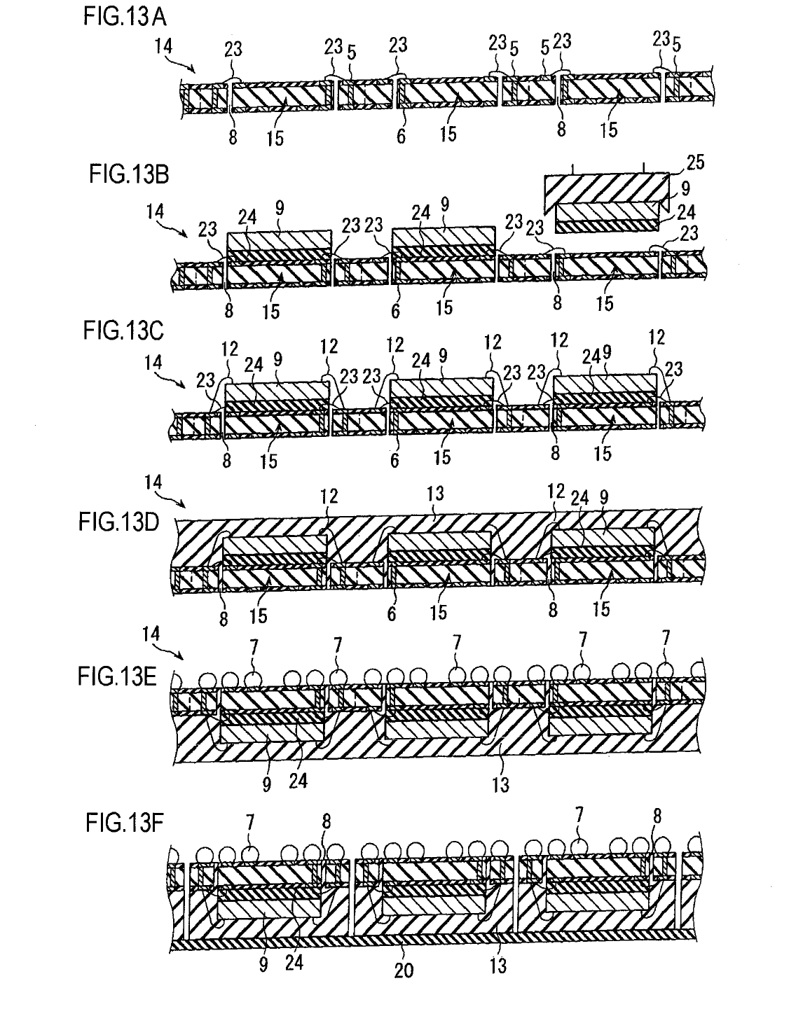

A method for manufacturing the semiconductor device 1 according to the sixth example will be described with reference to FIGS. 13 A to 13F.

First, as shown in FIG. 13A, the wiring motherboard 14 divided into pieces of the product forming portions 15 by the slits 8 is prepared, and using a wire bonding apparatus not shown in the drawing, the divided parts of the wiring substrate 2 are electrically connected with the conductive wires 23. The wiring motherboard divided into pieces of the product forming portions 15 by the slits 8 can be obtained, for instance, by first preparing the wiring motherboard 14 shown in FIGS. 7 and 8A and partially dicing the wiring motherboard 14 along with the marks 21.

Then, as shown in FIG. 13B, using a die bonding apparatus 25, the semiconductor chip 9 having the DAF 24 attached to its bottom surface is die-bonded over the wires 23 formed on each product forming portion 15. The adhesive provided on the bottom surface of the semiconductor chip 9 gets between the wires 23 and the semiconductor chip 9 is glued and fixed on the wiring substrate 2.

After this, using a wire bonding apparatus not shown in the drawing, the electrode pads 11 of the semiconductor chip 9 and the connection pads 5 are wired with the conductive wire 12 as shown in FIG. 13 (c).

Next, as shown in FIG. 13D, the sealing body 13, made of insulating resin, integrally covering the product forming portions 15 of the wiring motherboard 14 is formed using a transfer molding apparatus. On the wiring motherboard 14, the slits 8 are formed along the direction in which the sealing resin is injected from the gate, therefore the resin can be successfully filled into the slits 8. The adhesiveness of the wiring substrate 2 and the sealing resin (the sealing body 13) can be improved by filling the slits 8 with the sealing resin as well.

Next, as shown in FIG. 13E, using a ball mounter not shown in the drawing, the solder balls 7 are mounted on top of the plurality of lands 6 disposed in a grid on the other surface of the wiring motherboard 14 and the bump electrodes, which will become the external terminals, are formed.

Next, as shown in FIG. 13F, the semiconductor device 1 shown in FIG. 12 can be obtained by dicing the wiring motherboard 14 along with the dicing lines using a dicing apparatus not shown in the drawing and dividing it into pieces of the product forming portions 15.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

For instance, the present invention is applied to a BGA-type semiconductor device in the present example, however, it may be applied to a semiconductor device utilizing a wiring substrate, such as an LGA (Land Grid Array) type or MCP (Multi-chip Package) type.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor device, comprising:
a semiconductor chip mounted on a wiring substrate, said wiring substrate comprising a base member having a predetermined conductive pattern formed on both surfaces of the base member, wherein
said conductive pattern and said semiconductor chip are electrically connected, and slits that penetrate said base member in a vertical direction of said base member are provided.

2. The semiconductor device as defined in claim 1, wherein said slits are formed across said base member in a direction perpendicular to said vertical direction.

3. The semiconductor device as defined in claim 1, wherein said predetermined conductive pattern includes a plurality of conductive areas disposed interposing said slits therebetween, further comprising a connecting wiring that electrically connects said conductive areas so as to bridge said slits.

4. The semiconductor device as defined in claim 1, wherein said slits are disposed near edge ends of said semiconductor chip.

5. The semiconductor device as defined in claim 1, further comprising a plurality of external terminals provided on said wiring substrate wherein said slits are formed between a first external terminal, which is one of said external terminals located outermost in a predetermined direction, and a second external terminal, which is one of said external terminals located inside of said first external terminal in said predetermined direction and adjacent to said first external terminal, so as to extend in a direction perpendicular to said predetermined direction.

6. The semiconductor device as defined in claim 1, wherein said slits penetrate said wiring substrate in the vertical direction of said wiring substrate.

7. The semiconductor device as defined in claim 1, wherein said slits are filled with a resin.

8. The semiconductor device as defined in claim 7, wherein said semiconductor chip is sealed with a predetermined resin and the resin that fills said slits is said predetermined resin.

9. The semiconductor device as defined in claim 8 wherein said slits are provided in a direction in which said predetermined resin is injected when said semiconductor chip is sealed with said predetermined resin.

10. The semiconductor device as defined in claim 1, wherein said semiconductor chip is flip-chip mounted on said wiring substrate.
